(19) United States
(12) Patent Application Publication
(10) Pub. No.: US 2013/0032911 A1
(43) Pub. Date: Feb. 7, 2013

(54) MAGNETIC MEMORY DEVICE AND FABRICATION METHOD THEREOF

(71) Applicants: Dong Ha JUNG, Ichon-si (KR); Ki Seon PARK, Ichon-si (KR); Su Ryun MIN, Ichon-si (KR)

(72) Inventors: Dong Ha JUNG, Ichon-si (KR); Ki Seon PARK, Ichon-si (KR); Su Ryun MIN, Ichon-si (KR)

(21) Appl. No.: 13/251,522

(22) Filed: Oct. 3, 2011

(30) Foreign Application Priority Data
Aug. 5, 2011 (KR) 10-2011-0078270

(51) Int. Cl. H01L 43/10; H01L 43/12

(52) U.S. Cl. 257/421; 438/3; 257/E43.005; 257/E43.006

(57) ABSTRACT

A vertical magnetic memory device includes a pinned layer including a plurality of first ferromagnetic layers that are alternately stacked with at least one first spacer, wherein the pinned layer is configured to have a vertical magnetization, a free layer including a plurality of second ferromagnetic layers that are alternately stacked with at least one second spacer, and a tunnel barrier coupled between the pinned layer and the free layer.

### CROSS-REFERENCES TO RELATED APPLICATION

The present application claims priority under 35 U.S.C. §119(a) to Korean application number 10-2011-0078270, filed on Aug. 5, 2011, in the Korean Intellectual Property Office, which is incorporated herein by reference in its entirety as set forth in full.

### to BACKGROUND

1. Technical Field

The present invention relates to a semiconductor memory device, and more particularly, to a magnetic memory device and a fabrication method thereof.

2. Related Art

A magnetic memory device stores information using a magnetic field and provides low power consumption, durability and fast operation speeds. Moreover, since a magnetic memory device has a nonvolatile characteristic where data can be maintained even in a power-off state, its use as a portable memory is being considered.

As an example of a magnetic memory device, an MRAM (magnetoresistive random access memory) with a gigabit storage is being developed using a tunnel magnetoresistance (TMR) device.

Here, a tunnel magnetoresistance effect is obtained by a pair of ferromagnetic layers and a tunnel insulation layer interposed therebetween. With respect to the tunnel magnetoresistance effect, since magnetic coupling does not substantially occur between the ferromagnetic layers, a large magnetic resistance can be obtained even in a weak magnetic field condition. Compared to a giant magnetoresistance (GMR) device, a TMR device may have a higher magnetoresistance and lower switching current for programming data.

In being manufactured, a magnetic memory device has developed from a device in which ferromagnetic layers are horizontally magnetized to a device in which ferromagnetic layers are vertically magnetized. While CoFeB has been used as a ferromagnetic substance for causing horizontal magnetization, CoFeB may also be used as a vertical magnetization substance.

FIG. 1 is a diagram illustrating the structure of a typical vertical magnetic memory device.

Referring to FIG. 1, the vertical magnetic memory device has a structure in which a seed layer, a pinned layer, a tunnel barrier, a free layer and a capping layer are stacked. As a material of the pinned layer and the free layer, CoFeB may be used.

Here, in fabricating a vertical magnetic memory device using CoFeB, the thickness of each of the pinned layer and the free layer may be limited to 2.2 nm or less because at a larger thickness, vertical magnetization characteristics start to disappear and horizontal magnetization characteristics start to gain strengths. Thus, when using CoFeB for a vertical magnetic memory device, the thickness of each of the pinned layer and the free layer is to be maintained at 2.2 nm or less. However, if the thickness of the pinned layer or the free layer decreases to 2.2 nm or less, thermal stability starts to deteriorate.

During experiments, in the case of a magnetic memory device using CoFeB, thermal stability was detected to be about 43 at a device manufactured using 40 nm process. However, a magnetic memory device is desired to have a thermal stability target of about 60. Thus, in a vertical magnetic memory device using CoFeB, adequate thermal stability is difficult to obtain.

Since, as discussed above, in using CoFeB in a magnetic memory device, while vertical magnetization characteristics may be obtained while thermal stability deteriorates when CoFeB layer is 2.2 nm or less in thickness and opposite characteristics are obtained when CoFeB layer is larger than 2.2 nm in thickness, it is difficult to use CoFeB in a vertical magnetic memory device.

### SUMMARY

In one embodiment of the present invention, a vertical magnetic memory device includes: a pinned layer including a plurality of first ferromagnetic layers that are alternately stacked with at least one first spacer, wherein the pinned layer is configured to have a vertical magnetization; a free layer including a plurality of second ferromagnetic layers that are alternately stacked with at least one second spacer; and a tunnel barrier coupled between the pinned layer and the free layer.

In another embodiment of the present invention, a vertical magnetic memory device includes: capping layer and formed by alternately and repeatedly stacking a plurality of ferromagnetic layers with a plurality of spacers, wherein two of the ferromagnetic layers contact the seed layer and the capping layer, respectively.

In another embodiment of the present invention, a method for fabricating a vertical magnetic memory device including a pinned layer, a free layer, and a tunnel barrier formed between the pinned layer and the free layer includes: forming the pinned layer by stacking a plurality of first ferromagnetic layers alternately with at least one first spacer, wherein the pinned layer is configured to have a vertical magnetization; and forming the free layer by stacking a plurality of second ferromagnetic layers with at least one second spacer.

### BRIEF DESCRIPTION OF THE DRAWINGS

Features, aspects, and embodiments are described in conjunction with the attached drawings, in which:

FIG. 1 is a diagram illustrating the structure of a conventional vertical magnetic memory device;

FIG. 2 is a configuration diagram of a magnetic memory device in accordance with an embodiment of the present invention;

FIG. 3 is a configuration diagram of a magnetic memory device in accordance with another embodiment of the present invention; and

FIG. 4 is a graph illustrating coupling characteristics between a ferromagnetic layer and a spacer in the magnetic memory device according to the present invention.

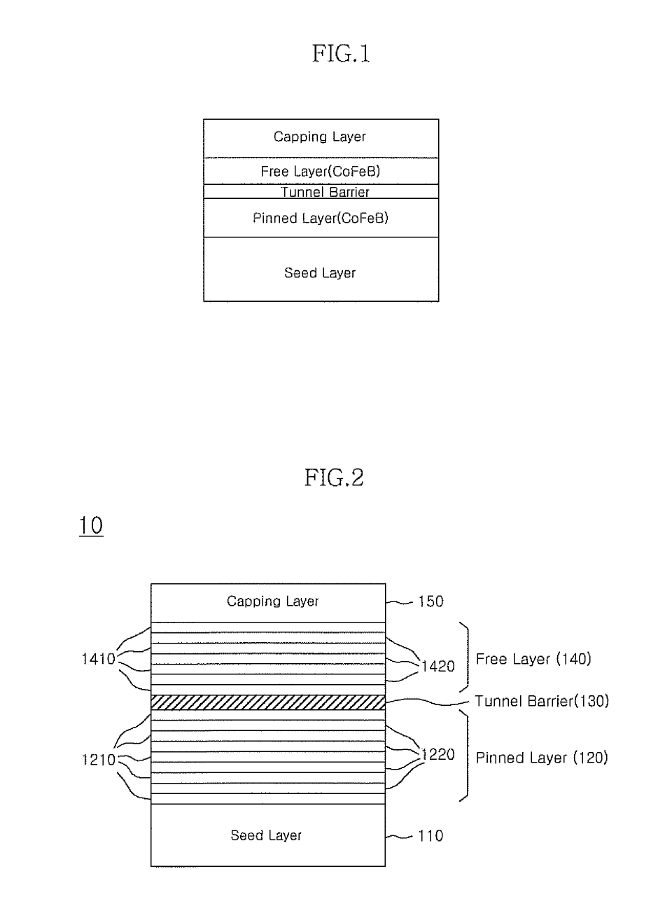

### DETAILED DESCRIPTION

Hereinafter, a magnetic semiconductor device and a fabrication method thereof according to the present invention will be described below with reference to the accompanying drawings through exemplary embodiments.

FIG. 2 is a configuration diagram of a magnetic memory device in accordance with an embodiment of the present invention.

Referring to FIG. 2, a vertical magnetic memory device 10 in accordance with an embodiment of the present invention has a structure in which a seed layer 110, a pinned layer 120, a tunnel barrier 130, a free layer 140 and a capping layer 150 are stacked.

In the pinned layer 120 and the free layer 140, ferromagnetic layers 1210 and 1410 and spacers 1220 and 1420 may be alternately stacked in a repeated manner. In this regard, the pinned layer 120 is formed to have the overall height greater than that of the free layer 140 so that proper functions of the pinned layer 120 are maintained.

In forming the pinned layer 120 to be higher than the free layer 140, the number of stacked layers or the height of each stacked layer may be controlled.

The vertical magnetic memory device 10 shown in FIG. 2 represents the case in which the number of stacked layers in the pinned layer 120 is controlled to be greater than the number of stacked layers of the free layer 140. This is described in detail as follows.

In FIG. 2, the pinned layer 120 may be formed by repeatedly stacking m (m is a natural number greater than or equal to or 2) layers of a compound material including CoFe as a constituent and the spacer 1220 in total, where the top layer is the ferromagnetic layer 1210.

The free layer 140 may be formed by repeatedly stacking n (n is a natural number smaller than m) layers of a compound material including CoFe as a constituent and the spacer 1420 in total, where the top layer is the ferromagnetic layer 1410.

The ferromagnetic layers 1210 and 1410 forming the pinned layer 120 and the free layer 140, respectively, may each be formed of a compound material including CoFe as a constituent such as CoFeB, CoFe, CoFeBTa, and CoFeBSl. The thickness of each of the ferromagnetic layers 1210 and 1410 may be set to 0.1˜2.2 nm. Each of the spacers 1220 and 1420 forming the pinned layer 120 and the free layer 140 may have a thickness of 0.2˜2 nm and may be formed as an oxide spacer such as a MgO layer, a metal oxide spacer such as Al₂O₃, TiO₂, HfO₂, ZrO₂ or Ta₂O₃ layer or a metal spacer such as Ru, Ta, W, Al or Ti layer. Here, the spacers 1210 and 1410 each cause an appropriate magnetic coupling so that the pinned layer 120 and the free layer 140 that are each made up of multiple layers can operate as if it was made with a single, unitary layer while maintaining thermal stability by having a sufficient overall thickness and avoiding a loss of vertical magnetization by having each individual layer with a thickness less than or equal to 2.2 nm despite having the overall thickness of the pinned layer 120 and the free layer 140 being greater than 2.2 nm.

As the tunnel barrier 130, an MgO layer may be used. In this regard, when MgO is grown on a crystal face (for example, 110), TMR may be increased by a factor or about 10 at a room temperature.

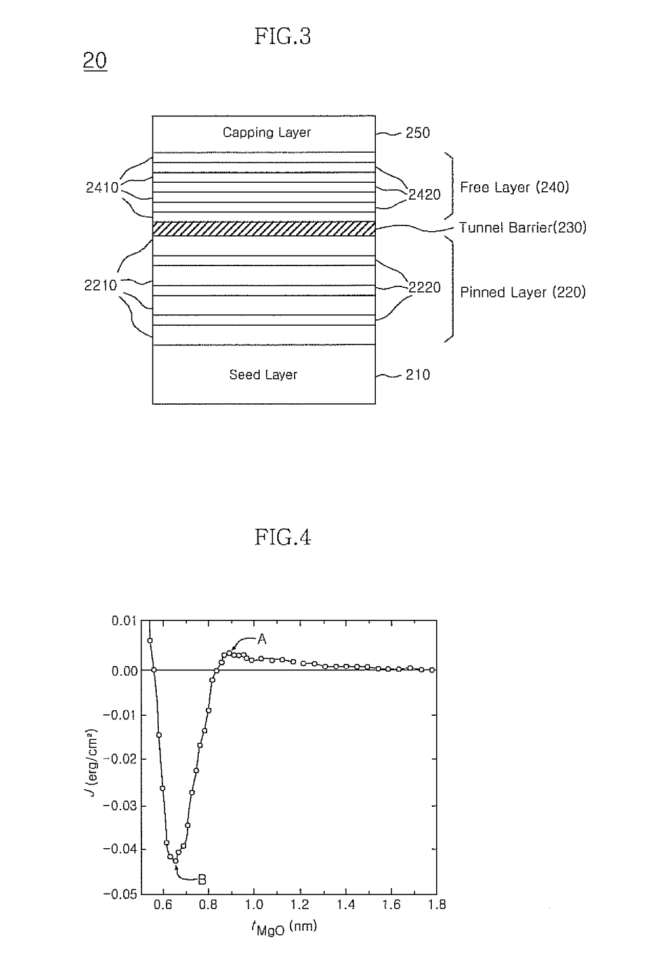

FIG. 3 is a configuration diagram of a magnetic memory device in accordance with another embodiment of the present invention.

Referring to FIG. 3, a vertical magnetic memory device 20 in accordance with another embodiment of the present invention includes a seed layer 210, a pinned layer 220, a tunnel barrier 230, a free layer 240 and a capping layer 250.

In the exemplary embodiment, the pinned layer 220 and the free layer 240 have structures in which ferromagnetic layers 2210 and 2410 and spacers 2220 and 2420 are alternately stacked a number of times such that the ferromagnetic layers 2210 and 2410 are the top layers in each of the pinned layer 220 and the free layer 240. Here, in order to form the pinned layer 220 to have an overall height greater than that of the free layer 240, the height of each of the ferromagnetic layers 2210 constituting the pinned layer 220 is controlled to be higher than the height of each of the ferromagnetic layers 2410 constituting the free layer 240. Here, the heights of the ferromagnetic layers 2210 may be the same or different, and the heights of the ferromagnetic layers 2410 may be the same or different.

The pinned layer 220 may be formed by repeatedly stacking x (x is a natural number equal to or greater than 2) number of ferromagnetic layers 2210 of a compound material including CoFe as a constituent and the spacer 2220 in total so that the top layer is the ferromagnetic layer 2210.

The free layer 240 may be formed by repeatedly stacking the x number of the ferromagnetic layer 2410 that are each made of a compound material including CoFe as a constituent and the spacer 2420, where the top layer is the ferromagnetic layer 2410.

The ferromagnetic layers 2210 and 2410 of the pinned layer 220 and the free layer 240, respectively, may be formed of a compound material substance including CoFe as a constituent such as CoFeB, CoFe, CoFeBTa and CoFeBSi. According to an example, the thickness of the ferromagnetic layer 2210 of the pinned layer 220 is set to 0.1˜2.2 nm, and the thickness of the ferromagnetic layer 2410 constituting the free layer 240 is set to be smaller than the thickness of the ferromagnetic layer 2210 in the pinned layer 220.

Each of the spacers 2220 and 2420 of the pinned layer 220 and the free layer 240 may be formed to have a thickness of 0.2˜2 nm and may be formed of an oxide spacer such as an MgO spacer, a metal oxide spacer such as an Al₂O₃, TiO₂, HfO₂, ZrO₂ and Ta₂O₃ spacer or a metal spacer such as a Ru, Ta, W, Al and Ti spacer.

As the tunnel barrier 230, a MgO layer may be used. Here, when MgO is grown on a crystal face (for example, 210), TMR may be increased by a factor of about 10 at a room temperature.

In reference to the vertical magnetic memory devices shown in FIGS. 2 and 3, formation of an oxide spacer between ferromagnetic layers constituting a pinned layer and a free layer by using MgO are as follows.

When the spacers 1220, 1420, 2220 and 2420 are formed using MgO, the thickness of each of the ferromagnetic layers 1210, 1410, 2210 and 2410 may be decreased without sacrificing the overall functions. Also, the adjacent ones of constituent magnetic layers of each of ferromagnetic layers 1210, 1410, 2210 and 2410 are ferromagnetically and antiferromagnetically coupled with each other, as appropriate, by the MgO spacers 1220, 1420, 2220, and 2420. Here, a sufficient overall volume/thickness for each of the pinned layers 120 and 220 and the free layers 140 and 240 are obtained to avoid a loss of vertical magnetization while decreasing the thickness of each of the ferromagnetic layers 1210, 1410, 2210 and 2410 to avoid of a vertical magnetization. Here, when a compound material including CoFe as a constituent is used as the material of the pinned layers 120 and 220 and the free layers 140 and 240, the ferromagnetic layers 1210, 1410, 2210 and 2410 may be formed to have a thickness equal to or less than 2.2 nm so that vertical magnetization characteristics are not lost and a sufficient overall volume/thickness for each of the pinned layers 120 and 220 and the free layers 140 and 240 are obtained so that adequate thermal stability is obtained.

FIG. 4 is a graph illustrating coupling characteristics between a ferromagnetic layer and a spacer in the magnetic memory device according to an exemplary embodiment of the present invention.

FIG. 4 shows coupling characteristics between contact surfaces when a MgO layer is placed as a spacer between two ferromagnetic layers.

In terms of ferromagnetic coupling characteristics, it is shown that a coupling energy J (erg/cm²) reaches a maximum A when the thickness of a MgO layer serving as a spacer is 0.9 nm. In the case of antiferromagnetic coupling characteristics, it is shown that a coupling energy J (erg/cm²) reaches a maximum B when the thickness of a MgO layer serving as a spacer is 0.6˜0.7 nm.

Here, when the MgO spacer is interposed between ferromagnetic layers, any of the ferromagnetic coupling characteristics and the antiferromagnetic coupling characteristics may be obtained by adjusting the thickness of the MgO spacer, and thus, the two ferromagnetic layers may be coupled antiferromagnetically or ferromagnetically. By using appropriate magnetic couplings in a pinned layer or a free layer, the thickness of each of the ferromagnetic layers may be minimized while a sufficient overall volume/thickness of the pinned layer or the free layer is obtained.

The magnetic memory devices shown in FIGS. 2 and 3 include ferromagnetic layers having, for example, CoFeB magnetic layers and MgO spacers that are alternately stacked between the seed layers 110 and 210 and the capping layers 150 and 250, respectively. Here, by using a MgO spacer as a tunnel barrier, a magnetic element formed on one side of the tunnel barrier may serve as a pinned layer, and a magnetic element formed on the other side of the tunnel barrier may serve as a free layer.

In having the pinned layer to operate independently of the magnetization direction of the free layer, the tunnel barrier is formed (for example, by selecting one of MgO spacers that are alternatively stacked with CoFeB magnetic layers to form the free layer and the pinned layer) so that the height of the pinned layer is higher than the height of the free layer, where, according to an example, such a height determines the independence of the operation.

In the exemplary embodiments of the present invention, when fabricating a vertical magnetic memory device, a pinned layer and a free layer are formed using a compound material including CoFe as a constituent. According to an example, by alternately stacking ferromagnetic layers made of a compound material including CoFe as a constituent and having a height of 2.2 nm or less, the vertical magnetization characteristics of a ferromagnetic layer may be maintained and the overall volume/thickness of each of the pinned layer and the free layer may be sufficient to obtain adequate thermal stability.

Here, when under 40 nm processes are used for manufacturing semiconductor devices such as a 2× nm level, vertical magnetization characteristics are maintained while obtaining sufficient volumes/thicknesses of a pinned layer and a free layer to obtain thermal stability. Thus, a vertical magnetic memory device having smaller dimensions may be obtained.

While specific embodiments have been described above, they are exemplary only. Accordingly, a magnetic semiconductor device and the fabrication method thereof as described herein should not be limited to the specific embodiments but should be broadly construed to include any other reasonably suitable devices/methods consistent with the above-described features of the exemplary embodiments.

What is claimed is:

1. A vertical magnetic memory device comprising:
a pinned layer including a plurality of first ferromagnetic layers that are alternately stacked with at least one first spacer, wherein the pinned layer is configured to have a vertical magnetization;
a free layer including a plurality of second ferromagnetic layers that are alternately stacked with at least one second spacer; and
a tunnel barrier coupled between the pinned layer and the free layer.

2. The vertical magnetic memory device according to claim 1, wherein each of the at least one first spacer and the at least one second spacer is formed of any one selected among an oxide spacer, is a metal oxide spacer and a metal spacer.

3. The vertical magnetic memory device according to claim 1, wherein each of the at least one first spacer and the at least one second spacer is formed of MgO.

4. The vertical magnetic memory device according to claim 1, wherein each of the at least one first spacer and the at least one second spacer is formed of a substance selected from a group including Al₂O₃, TiO₂, HfO₂, ZrO₂ and Ta₂O₃.

5. The vertical magnetic memory device according to claim 1, wherein each of the at least one first spacer and the at least one second spacer is formed of a substance selected from a group including Ru, Ta, W, Al and Ti.

6. The vertical magnetic memory device according to claim 1, wherein the tunnel barrier is formed of MgO.

7. The vertical magnetic memory device according to claim 1, wherein the pinned layer is formed to have an overall height greater than an overall height of the free layer.

8. The vertical magnetic memory device according to claim 1, wherein the total number of the stacked first ferromagnetic layers is and the at least one first spacer in the pinned layer is more than the total number of the stacked second ferromagnetic layers and the at least one second spacer in the free layer.

9. The vertical magnetic memory device according to claim 1, wherein each of the first ferromagnetic layers and the second ferromagnetic layers has a thickness ranging between 0.1 nm and 2.2 nm.

10. The vertical magnetic memory device according to claim 1 wherein each of the first and second spacers has a thickness ranging between 0.2 nm and 2 nm.

11. The vertical magnetic memory device according to claim 1, wherein a height of each one of the first ferromagnetic layers is higher than a height of each one of the second ferromagnetic layers.

12. The vertical magnetic memory device according to claim 1, wherein the total number of the stacked first ferromagnetic layers and the at least one first spacer in the pinned layer is equal to the total number of the stacked second ferromagnetic layers and the at least one second spacer in the free layer.

13. The vertical magnetic memory device according to claim 1, wherein the top layer of the pinned layer is one of the first ferromagnetic layers.

14. The vertical magnetic memory device according to claim 1, wherein the first ferromagnetic layers are made of a compound material including CoFe as a constituent.

15. The vertical magnetic memory device according to claim 1, wherein the first ferromagnetic layers are configured to be ferromagnetically coupled to each other via the at least one spacer.

16. The vertical magnetic memory device according to claim 1, wherein the first ferromagnetic layers are configured to be antiferromagnetically coupled to each other via the at least one spacer.

17. The vertical magnetic memory device according to claim 1, wherein the free layer is configured to have a vertical magnetization.

18. A method for fabricating a vertical magnetic memory device including a pinned layer, a free layer, and a tunnel barrier formed between the pinned layer and the free layer, the method comprising:
forming the pinned layer by stacking a plurality of first ferromagnetic layers alternately with at least one first spacer, wherein the pinned layer is configured to have a vertical magnetization; and
forming the free layer by stacking a plurality of second ferromagnetic layers with at least one second spacer.

19. The method according to claim 18, wherein each of the at least one first spacer and the at least one second spacer is formed of MgO.

20. The method according to claim 18, wherein each of the at least one first spacer and the at least one second spacer is formed of a substance selected from a group including Al₂O₃, TiO₂, HfO₂, ZrO₂ and Ta₂O₃.

21. The method according to claim 18, wherein each of the at least one first spacer and the at least one second spacer is formed of a substance selected from a group including Ru, Ta, W, Al and Ti.

22. A vertical magnetic memory device comprising:
a magnetic element disposed between a seed layer and a capping layer and formed by alternately and repeatedly stacking a plurality of ferromagnetic layers with a plurality of spacers, wherein two of the ferromagnetic layers contact the seed layer and the capping layer, respectively.

23. The vertical magnetic memory device according to claim 22, wherein the spacers are each formed of MgO.

24. The vertical magnetic memory device according to claim 22, wherein one of the spacers is configured to operate as a tunnel barrier, a magnetic element formed on one side of the tunnel barrier is configured to operate as a pinned layer, and a magnetic element formed on the other side of the tunnel barrier is configured to operate as a free layer.

25. The vertical magnetic memory device according to claim 24, wherein a height of the magnetic element forming the pinned layer is higher than a height of the magnetic element forming the free layer.

26. The vertical magnetic memory device according to claim 22, wherein the ferromagnetic layers each have a vertical magnetization.
